(19) United States
(12) Patent Application Publication
(10) Pub. No.: US 2002/0017913 A1
(43) Pub. Date: Feb. 14, 2002

(54) Electro-optic sampling probe

(76) Inventors: Toshiyuki Yagi, Tokyo (JP); Katsushi Ohta, Tokyo (JP); Tadao Nagatsuma, Tokyo (JP); Mitsuru Shinagawa, Tokyo (JP); Junzo Yamada, Tokyo (JP)

Correspondence Address: DARBY & DARBY P.C., 805 Third Avenue, New York, NY, 10022, US

(21) Appl. No.: 09/911,661

(22) Filed: Jul. 24, 2001

(30) Foreign Application Priority Data
Jul. 28, 2000 (JP) 2000-230058

(51) Int. Cl. G01R 31/308

(52) U.S. Cl. 324/753

(57) ABSTRACT

The electro-optic sampling probe of the present invention comprising: an electro-optic element that is connected to wiring on a surface of a wafer to be measured and whose optical characteristics change when an electric field is applied via the wiring; and an electro-optic sampling optical system module that is provided internally with polarizing beam splitters, wavelength plates, and photodiodes and that splits laser beam irradiated from outside that is transmitted through the electro-optic element and is further reflected at a surface of the electro-optic element that faces the wiring and converts it into electrical signals. Furthermore, the electro-optic sampling optical system module comprises: a ¼wavelength plate for changing laser beam that is elliptically polarized back into linearly polarized light before it enters the electro-optic sampling optical system module; and a ½wavelength plate for adjusting a polarization direction of the linearly polarized light.

### BACKGROUND OF THE INVENTION

1. Field of the Invention

The present invention relates to an electro-optic sampling probe for focusing an electric field generated by a signal to be measured on an electro-optic crystal, irradiating light pulses created based on timing signals onto the electro-optic crystal, and observing the waveform of the signal to be measured using the state of polarization of the irradiated light pulses, and particularly, to an electro-optic sampling probe in which the probe has an improved optical system.

2. Description of the Related Art

It is possible to observe the waveform of a signal to be measured by acting an electric field generated by the signal to be measured on an electro-optic crystal, irradiating laser beam onto the electro-optic crystal, and observing the waveform of the signal to be measured by the state of polarization of the laser beam. In this case, the laser beam is given the form of light pulses and the signal to be measureds then sampled, the observation can be made at an extremely high time resolution. The electro-optic sampling probe utilizes an electro-optic probe that makes use of this principle.

This electro-optic sampling probe (abbreviated below to EOS probe) has following remarkable features in comparison with a conventional probes using electrical probes.

(1) The signal is easily measured since a ground wire becomes unnecessary when the measurement is performed.

(2) A high input impedance can be obtained since the metal pin on the tip of the electro-optic probe is insulated from the circuit system, and therefore, the point that is measured is not significantly disturbed.

(3) The measurement can be performed over a wide range of frequencies including the order of GHz since pulsed light is used.

(4) The measurement can be performed even with fine wiring that it is not physically possible to contact with a metal pin by contacting an electro-optic crystal with a wafer such as an IC wafer and focusing laser beam onto the wiring on the IC wafer. The structure of a conventional EOS probe will be explained with reference to FIG. 4.

In FIG. 4, reference numeral 1 denotes an IC wafer that is connected to the outside via power supply lines and signal lines. Reference numeral 2 denotes an electro-optic element made of an electro-optic crystal. Reference numeral 3 denotes an objective lens used for focusing light irradiated onto the electro-optic element 2. Reference numeral 4 denotes a probe main body that is provided with a dichroic mirror 4a and a half mirror 4b. Reference numeral 6a denotes an EOS optical system module (referred to below as an EOS optical system) comprising a photodiode, a polarizing beam splitter, a wavelength plate, and the like. Reference numeral 69 denotes a portion for the attachment of an optical fiber.

Reference numeral 7 denotes a halogen lamp for illuminating the IC wafer 1 being measured. Reference numeral 8 denotes an infrared camera for verifying the positioning in order to focus the light onto the wiring of the IC wafer 1. Reference numeral 9 denotes a suctioning stage for fixing the IC wafer in place using suction that is able to be moved by minute amounts in the directions of the x-axis, y-axis, and z-axis that are orthogonal. Reference numeral 10 denotes a surface plate (only partially illustrated) on which the suctioning stage 9 is mounted Reference numeral 11 denotes an optical fiber for transmitting laser beam emitted from the outside and is fixed by the optical fiber attachment portion 69.

Next, the light pathway of the laser beam which is emitted from the outside will be explained with reference to FIG.4. In FIG. 4, the light path of the laser beam inside the probe main body 4 is denoted by the reference number A.

The laser beam that enters into the EOS optical system 6a via the optical fiber 11 is converted to a parallel light, and travels straight through the inside gof the EOS optical system 6a and enters into the probe main body 4. The light beam further travels straight through the probe main body 4 and is bent 90 degrees by the dichroic mirror 4a, and is focused by the objective lens 3 on the surface facing the IC wafer 1 of the electro-optic element 2 that is placed above the wiring on the IC wafer 1.

Here, the wavelength of the laser beam irradiated onto the EOS optical system 6a via the optical fiber 11 is 1550 [nm]. However, the characteristics of the dichroic mirror 4a used in this system are such that 5% of light having a 1550 [nm] wavelength is transmitted while 95% is reflected. Consequently, 95% of the light emitted from the laser beam source is reflected and bent at an angle of 90 degrees.

A conductive mirror is evaporated on the surface of the electro-optic element 2 facing the IC wafer 1 and the laser beam is reflected by the conductive mirror and once again converted to a parallel light by the objective lens 3. The light returns to the EOS optical system 6a by the same light path and is irradiated onto the photodiode inside the EOS optical system 6a. The structure of this EOS optical system 6a is described below in detail.

Next, a description will be given of the light path of the light emitted by the halogen lamp 9 and the operation to position the IC wafer 1 when the IC wafer 1 is positioned using a halogen lamp 7 and an IR camera 8. In FIG. 4, the light path of the light emitted from the halogen lamp 7 is denotrd by reference number B.

The halogen lamp 7 used here emits light having a wavelength in the range of 400 [nm] to 1650 [nm].

The light emitted from the halogen lamp 7 is bent at an angle of 90 degrees by the half mirror 4b. This light passes straight through the dichroic mirror 4a and illuminates the IC wafer 1. The half mirror 4b used here is one in which the intensities of the reflected light and the transmitted light are equal.

The IR camera 8 photographs a portion of the IC wafer 1 that has been illuminated by the halogen lamp 7 within the visual field of the objective lens 3 and displays this infrared image on a monitor 8a. An operator adjusts the suctioning stage 9 in minute movements while looking at the image displayed on the monitor 8a such that the wiring on the wafer 1 that is to be measured comes into the visual field.

The operator also adjusts the suctioning stage 9 or the probe main body 4 such that the laser beam is focused on the point of the surface of the electro-optic element 2 on the wiring that is to be measured by verifying, using the image from the IR camera 8, the light irradiated onto the EOS optical system 6a via the optical fiber 11 that is reflected at the surface of the electro-optic element 2 on the wiring of the IC wafer 1 and then passes through the dichroic mirror 4a. At this time, because the dichroic mirror 4a has the characteristic of transmitting 5% of the light in the laser beam wavelength band, this laser beam can be verified using the IR camera 8.

Next, the operation for measuring the signal to be measured using the EOS probe shown in FIG. 4 will be explained.

When voltage is applied to the wiring on the wafer 1, the electric field thereof acts on the electro-optic element 2 and the phenomenon of the refractive index changing due to Pockels Effect occurs in the electro-optic element 2. As a result, the laser beam enters into the electro-optic element 2, is reflected at the surface thereof that faces the IC wafer 1, returns again along the same path and the polarization of the light is changed when the light is emitted from the electro-optic element 2. The laser beam with the changed polarization is then irradiated again into the EOS optical system 6a.

The change in the polarization of the light that is irradiated into the EOS optical system 6a is converted in the EOS optical system 6a into change in the light intensity. These light intensity change is then detected by a photodiode and converted into an electrical signal. The electrical signal applied to the wiring on the IC wafer 1 can then be measured by performing signal processing on the signal in a signal processing section (not illustrated).

Next, the structure of the EOS optical system 6a shown in FIG. 4 will be explained.

FIG. 5 is a diagram showing in detail the structure of the EOS optical system 6a. In FIG. 5, reference numerals 61, 64, and 67 denote ½ wavelength plates, and reference numeral 62 denotes a 1/4 wavelength plate. Reference numerals 63 and 66 denote polarizing beam splitters, and reference numeral 65 denotes a Faraday element. Reference numeral 68 denotes a collimate lens. Reference numerals 70 and 71 denote photodiodes for detecting laser beam, and reference numerals 72 and 73 denote focusing lenses for focusing laser beam. The differential output signals from these two photodiodes 70 and 71 become the signal of the results of the measurement. Reference numeral 11a denotes the end portion of the optical fiber 11 and the laser beam is emitted from here. This end portion 11a is fixed to the attachment portion 69. The attachment portion 69 can be moved by minute amounts in three orthogonal directions using the X-axis stage 69a, the Y-axis stage 69b, and the Z-axis stage 69c and performs the adjustment of the optical axis and the adjustment of the focal point of the collimate lens 68.

Note that the ½ wavelength plate 61 and the ¼ wavelength plate 62 are used to adjust the balance of the light entering the two photodiodes 67 and 68 and the adjustment is performed using a rotating stage 61a that rotates the ½ wavelength plate 61 around the optical axis of the laser beam and a rotating stage 62a that rotates the ¼ wavelength plate 62 around the optical axis of the laser beam.

The ½ wavelength plate 67 is used to adjust the polarization direction of the laser beam irradiated into the polarizing beam splitter 66. This adjustment is performed using a rotating stage 67a that rotates the ½ wavelength plate 67 around the optical axis of the laser beam.

The optical system formed by the ½ wavelength plate 64, the polarizing beam splitters 63 and 66, and the Faraday element 65 is known as a light isolator.

Next, the operation for measuring the electrical signal on the wiring on the IC wafer 1 using the EOS optical system 6a will be described.

Laser beam is supplied to the EOS optical system 6a from an external light source via the optical fiber 11. This laser beam is converted into a parallel light by the collimate lens 68. This parallel light travels straight through the EOS optical system 6a and is then bent at an angle of 90 degrees by the dichroic mirror 4a inside the probe main body 4 and focused by the objective lens 3. The focused laser beam passes through the electro-optic element 2 and arrives at the surface of the electro-optic element 2 that faces the wiring on the IC wafer 1.

At this time, due to the voltage applied to the wiring, the electric field of the voltage acts on the electro-optic element 2 and the phenomenon of the refractive index changing due to Pockels Effect occurs in the electro-optic element 2. As a result, when the laser beam that enters into the electro-optic element 2 is transmitted through the electro-optic element 2, the polarization of the light is changed. The laser beam with the changed polarization is then reflected by the mirror at the surface of the electro-optic element 2 on the wiring on the IC wafer 1, travels in reverse along the same optical path it traveled when it was irradiated onto the electro-optic element 2, and is irradiated into the EOS optical system 6a. This laser beam is then split by the light isolator described above, irradiated onto the photodiodes 70 and 71, and converted into electrical signals.

In compliance with the change in the voltage of the measured point (i.e. the wiring on the IC wafer), the change in the polarization brought about by the electro-optic element 2 form the differences in the outputs of the photodiode 70 and the photodiode 71. As a result, by detecting these output differences, it is possible to measure the electrical signal conveyed to the wiring on the IC wafer 1.

However, in the conventional electro-optic sampling probe, since a dispersion shifted fiber is used for the optical fiber 11, even if the incident light is linearly polarized, it is changed into arbitrarily elliptically polarized incident light inside the fiber by the forming state of the fiber cord. Therefore, the problem arises that it is not always possible to reduce insertion loss to the minimum even if the polarization direction of the incident light is adjusted.

### SUMMARY OF THE INVENTION

The present invention is provided in consideration of the above circumstances, and the object of the present invention is to provide an electro-optic sampling probe which can reducing to a minimum the insertion loss of incident light in the optical system of an electro-optic sampling probe.

The first aspect of the present invention is an electro-optic sampling probe, comprising: an electro-optic element that is connected to wiring on a surface of a wafer to be measured and whose optical characteristics change when an electric field is applied via the wiring; and an electro-optic sampling optical system module that is provided internally with polarizing beam splitters, wavelength plates, and photodiodes and that splits laser beam irradiated from outside that is transmitted through the electro-optic element and is further reflected at a surface of the electro-optic element that faces the wiring and converts it into electrical signals, wherein the electro-optic sampling optical system module comprises: a ¼ wavelength plate for changing laser beam that is elliptically polarized back into linearly polarized light before it enters into the electro-optic sampling optical system module; and a ½ wavelength plate for adjusting a polarization direction of linearly polarized light.

The second aspect of the present invention is an electro-optic sampling probe, comprising: an electro-optic element that is connected to wiring on a surface of a wafer to be measured and whose optical characteristics change when an electric field is applied via the wiring; and an electro-optic sampling optical system module that is provided internally with polarizing beam splitters, wavelength plates, and photodiodes and that splits laser beam irradiated from outside that is transmitted through the electro-optic element and is further reflected at a surface of the electro-optic element that faces the wiring and converts it into electrical signals, wherein the laser beam is irradiated into the electro-optic sampling optical system module using a polarization maintaining fiber, and a ½wavelength plate for adjusting a polarization direction of linearly polarized light is provided with the electro-optic sampling optical system module.

The third aspect of the present invention is an electro-optic sampling probe, comprising: an electro-optic element that is connected to wiring on a surface of a wafer to be measured and whose optical characteristics change when an electric field is applied via the wiring; and an electro-optic sampling optical system module that is provided internally with polarizing beam splitters, wavelength plates, and photodiodes and that splits laser beam irradiated from outside that is transmitted through the electro-optic element and is further reflected at a surface of the electro-optic element that faces the wiring and converts it into electrical signals, wherein the laser beam is irradiated into the electro-optic sampling optical system module using a polarization maintaining fiber, and the emission portion of the polarization maintaining fiber is capable of being rotated around an optical axis of the laser beam.

### BRIEF DESCRIPTION OF THE DRAWINGS

FIG. 1 is a front view showing the structure of the electro-optic sampling optical system module according to the first embodiment of the present invention.

FIG. 2 is a front view showing the structure of the electro-optic sampling optical system module according to the second embodiment of the present invention.

FIG. 3 is a front view showing the structure of the electro-optic sampling optical system module according to the third embodiment of the present invention.

FIG. 4 is a schematic diagram showing the structure of a conventional electro-optic sampling probe.

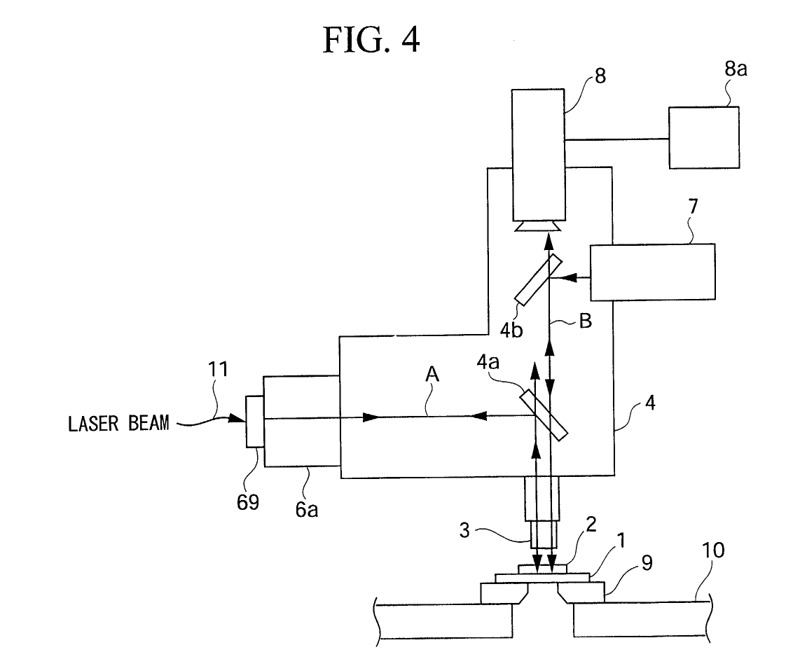

FIG. 5 is a front view showing the structure of a conventional EOS optical system.

### DESCRIPTION OF THE PREFERRED EMBODIMENTS

(First Embodiment)

The electro-optic sampling probe according to the first embodiment of the present invention will be described with reference to the drawings.

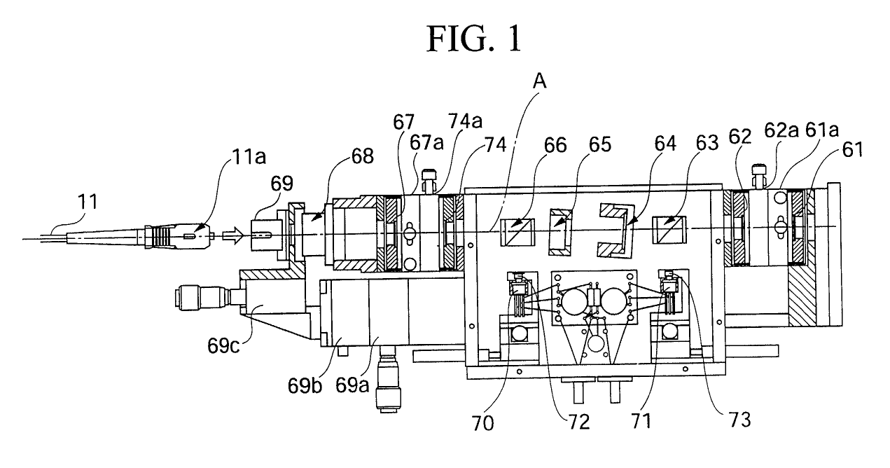

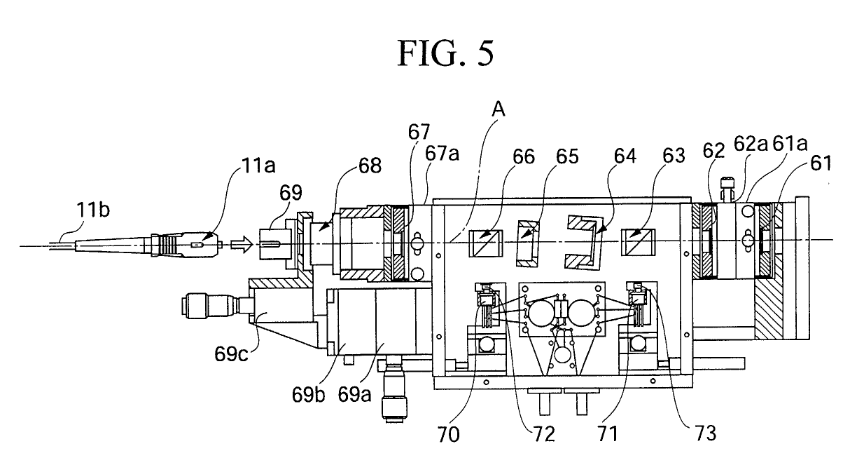

FIG. 1 is a front view showing the structure of the EOS optical system 6a of the first embodiment. In FIG. 1, the same reference numerals are given to the optical parts that are the same as those in the conventional probe shown in FIG. 5 and a description thereof is omitted. The probe shown in FIG. 1 differs from the conventional probe in that it is provided with a ¼ wavelength plate 74 between the optical fiber end portion 11a and the polarizing beam splitter 66, and a rotating stage 74a for rotating the ¼ wavelength plate 74 around the optical axis (reference numeral A shown in FIG. 1).

Next, the polarization state of the laser beam in the EOS optical system 6a in the first embodiment will be described. Since the optical fiber 11 is a dispersion shifted fiber, even if the light that is irradiated into this optical fiber 11 is linearly polarized, because of the forming state of the fiber code, it becomes changed into arbitrarily elliptically polarized light inside the optical fiber 11. This elliptically polarized light is emitted from the end portion 11a. However, since the light that is irradiated into the polarizing beam splitter 66 needs to be linearly polarized light, there is a large loss in the light emitted from the end portion 11a. Accordingly, the newly provided 1/4 wavelength plate 74 is rotated by the rotating stage 74a such that the elliptically polarized light is changed back into linearly polarized light. At this time, the angle of rotation of the ¼ wavelength plate 74 is adjusted while a check is maintained on the current in the photodiodes 70 and 71 in order that the angle when the S/N ratio reaches the optimum is held in that state. The above described measurement of the signal to be measured is performed while angle is held in that state.

In this way, by providing a ¼ wavelength plate 74 between the optical fiber end portion 11a and the polarizing beam splitter 66 and a rotating stage 74a for rotating this ¼ wavelength plate 74 around the optical axis (reference numeral A shown in FIG. 1), it is possible to reduce to a minimum the insertion loss of the incident light.

Note that, in FIG. 1, the ¼ wavelength plate 74 and the rotating stage 74a are provided between the polarizing beam splitter 66 and the rotating stage 67a, however, as long as the ¼ wavelength plate 74 and the rotating stage 74a are provided between the polarizing beam splitter 66 and the end portion 11a, then any position is acceptable.

(Second Embodiment)

Next, the electro-optic sampling probe according to the second embodiment will be described with reference to the drawings.

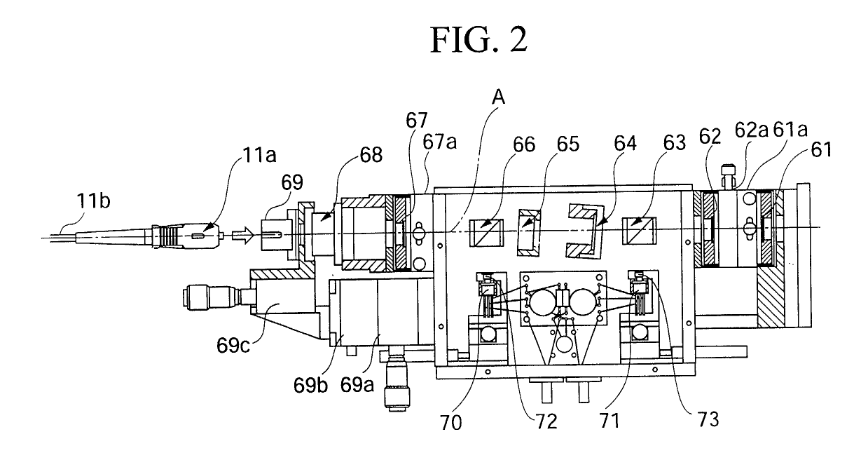

FIG. 2 is a front view showing the structure of the EOS optical system 6a of the second embodiment. In FIG. 2, the same reference numerals are given to the optical parts that are the same as those in the conventional probe shown in FIG. 5 and a description thereof is omitted. The probe shown in FIG. 2 differs from the conventional probe in that the optical fiber 11 has been replaced by a polarization maintaining fiber 11b.

In the second embodiment, because the polarization maintaining fiber 11b is used for the optical fiber 11, if the incident light is linearly polarized light, that polarization state is maintained. Therefore, if the polarization direction is adjusted using the ½wavelength plate 67, then it is possible to irradiate the light into the polarizing beam splitter 66 without there being any loss in the irradiated light.

In this way, because the polarization maintaining fiber 11b is used for the optical fiber 11, it is possible to reduce to a minimum the insertion loss of the incident light.

(Third Embodiment)

Next, the electro-optic sampling probe according to the third embodiment will be described with reference to the drawings.

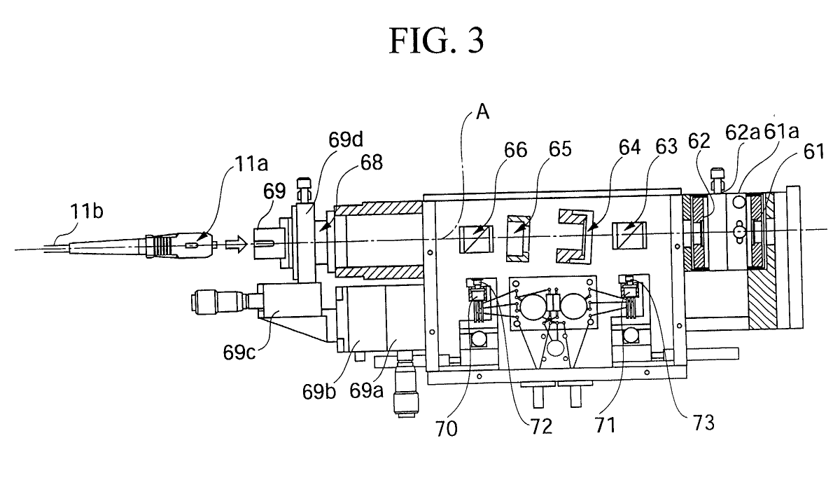

FIG. 3 is a front view showing the structure of the EOS optical system 6a of the third embodiment. In FIG. 3, the same reference numerals are given to the optical parts that are the same as those in the conventional probe shown in FIG. 5 and a description thereof is omitted. The probe shown in FIG. 3 differs from the conventional probe in that the optical fiber 11 has been replaced by a polarization maintaining fiber 11b, in that it is newly provided with a rotating stage 69d for rotating the attachment portion 69 around the optical axis (reference numeral A shown in FIG. 3), and in that the ½ wavelength plate 67 and the rotating stage 67a have been removed.

Next, the polarization state of the laser beam inside the EOS optical system 6a in the third embodiment will be described. The light that is emitted from the end portion 11a is emitted with the polarization state of the light that was irradiated into the polarization maintaining fiber 11b being maintained, however, the polarization direction is an arbitrary direction. Therefore, the polarization direction needs to be adjusted using the ½wavelength plate 67. In this third embodiment, since the end portion 11a can be rotated to around the optical axis by rotating the attachment portion 69 in which the end portion 11a is fixed, using the rotating stage 69d. As a result, by rotating the rotating stage 69d, it is possible to adjust the polarization direction in spite of the ½ wavelength plate 67 having been removed. At this time, the angle of rotation of the rotation stage 69d is adjusted while a check is maintained on the current in the photodiodes 70 and 71 in order that the angle when the S/N ratio reaches the optimum is held in that state. The above described measurement of the signal to be measured is performed while angle is held in that state.

In this way, because it is possible to rotate the attachment portion 69 to which the polarization maintaining fiber 11b has been fixed, it is possible to reduce to a minimum the insertion loss of the incident light and to also reduce the number of optical parts.

As has been described above, according to the present invention, the effect is obtained that it is possible to reduce to a minimum the insertion loss of incident light regardless of the forming state of the optical fiber cord. The result of this is that the effect is obtained that it is possible to achieve an improvement in the S/N ratio during a measurement.

What is claimed is:

1. An electro-optic sampling probe, comprising:
an electro-optic element that is connected to wiring on a surface of a wafer to be measured and whose optical characteristics change when an electric field is applied via the wiring; and
an electro-optic sampling optical system module that is provided internally with polarizing beam splitters, wavelength plates, and photodiodes and that splits laser beam irradiated from outside that is transmitted through said electro-optic element and is further reflected at a surface of said electro-optic element that faces said wiring and converts it into electrical signals, wherein
said electro-optic sampling optical system module comprises:
a ¼ wavelength plate for changing laser beam that is elliptically polarized back into linearly polarized light before it enters the electro-optic sampling optical system module; and
a ½ wavelength plate for adjusting a polarization direction of said linearly polarized light.

2. An electro-optic sampling probe, comprising:
an electro-optic element that is connected to wiring on a surface of a wafer to be measured and whose optical characteristics change when an electric field is applied via the wiring; and
an electro-optic sampling optical system module that is provided internally with polarizing beam splitters, wavelength plates, and photodiodes and that splits laser beam irradiated from outside that is transmitted through said electro-optic element and is further reflected at a surface of said electro-optic element that faces said wiring and converts it into electrical signals, wherein
said laser beam is irradiated into said electro-optic sampling optical system module using a polarization maintaining fiber, and
a ½ wavelength plate for adjusting a polarization direction of linearly polarized light is provided with said electro-optic sampling optical system module.

3. An electro-optic sampling probe, comprising:
an electro-optic element that is connected to wiring on a surface of a wafer to be measured and whose optical characteristics change when an electric field is applied via the wiring; and
an electro-optic sampling optical system module that is provided internally with polarizing beam splitters, wavelength plates, and photodiodes and that splits laser beam irradiated from outside that is transmitted through said electro-optic element and is further reflected at a surface of said electro-optic element that faces said wiring and converts it into electrical signals, wherein
said laser beam is irradiated into said electro-optic sampling optical system module using a polarization maintaining fiber, and an emission portion of said polarization maintaining fiber is capable of being rotated around an optical axis of said laser beam.
